(19) United States
(12) Patent Application Publication
(10) Pub. No.: US 2026/0206212 A1
(43) Pub. Date: Jul. 16, 2026

(54) SEMICONDUCTOR MEMORY DEVICE AND ELECTRONIC SYSTEM INCLUDING SAME

(71) Applicant: Samsung Electronics Co., Ltd., Suwon-si (KR)

(72) Inventors: Jongseon AHN, Suwon-si (KR); Joohang LEE, Suwon-si (KR); Donghwan KIM, Suwon-si (KR); Sewoon LEE, Suwon-si (KR)

(73) Assignee: Samsung Electronics Co., Ltd., Suwon-si (KR)

(21) Appl. No.: 19/300,161

(22) Filed: Aug. 14, 2025

(30) Foreign Application Priority Data
Jan. 15, 2025 (KR) 10-2025-0005927

(51) Int. Cl. H10B 12/00; H01L 23/00; H01L 23/522; H01L 25/18; H10B 80/00; H10D 80/30

(52) U.S. Cl. CPC H10B 12/482; H10B 80/00; H10D 80/30; H10W 20/42; H10W 90/00; H10W 80/312; H10W 80/327; H10W 90/297; H10W 90/792

(57) ABSTRACT

A semiconductor memory device includes a mold structure on a substrate and including a plurality of gate electrodes stacked and spaced apart from each other in a first direction, a channel structure penetrating through the mold structure, a bit line connected to the channel structure and extending in a second direction intersecting with the first direction, a cell via on the bit line, a dummy via on the bit line and spaced apart from the cell via in the second direction, an upper interlayer insulating film surrounding the cell via and the dummy via, a first upper bonding pad on the cell via, and a second upper bonding pad spaced apart from the first upper bonding pad in the second direction, wherein the upper interlayer insulating film covers a lower surface of the dummy via.

### CROSS-REFERENCE TO RELATED APPLICATION

This application claims priority to Korean Patent Application No. 10-2025-0005927, filed in the Korean Intellectual Property Office on Jan. 15, 2025, the entire contents of which are hereby incorporated by reference.

### BACKGROUND

### Field

The present disclosure relates to semiconductor memory devices and electronic systems including the same.

### Description of Related Art

There is a need for a semiconductor memory device capable of storing high-capacity data in an electronic system that uses or requires data storage. Accordingly, ways to increase the data storage capacity of the semiconductor memory devices are being studied. For example, as one of the methods for increasing the data storage capacity of the semiconductor device, a semiconductor device including three-dimensional arrangement of memory cells, instead of two-dimensional arrangement of memory cells, has been proposed.

### SUMMARY

In order to solve one or more problems (e.g., the problems described above and/or other problems not explicitly described herein), the present disclosure provides semiconductor memory devices capable of relatively easily identifying a defective location.

In order to solve one or more problems (e.g., the problems described above and/or other problems not explicitly described herein), the present disclosure provides electronic systems capable of relatively easily identifying a defective location.

In order to solve one or more problems (e.g., the problems described above and/or other problems not explicitly described herein), the present disclosure provides methods of manufacturing a semiconductor memory device capable of relatively easily identifying a defective location.

According to some example embodiments of the present disclosure, a semiconductor memory device may include a mold structure on a substrate and including a plurality of gate electrodes stacked and spaced apart from each other in a first direction, a channel structure penetrating through the mold structure, a bit line connected to the channel structure and extending in a second direction intersecting with the first direction, a cell via on the bit line, a dummy via on the bit line and spaced apart from the cell via in the second direction, an upper interlayer insulating film surrounding the cell via and the dummy via, a first upper bonding pad on the cell via, and a second upper bonding pad spaced apart from the first upper bonding pad in the second direction, wherein the upper interlayer insulating film covers a lower surface of the dummy via.

According to some example embodiments of the present disclosure, a semiconductor memory device may include a mold structure on a substrate, a channel structure penetrating through the mold structure and extending in a first direction, a first bit line connected to the channel structure and extending in a second direction intersecting with the first direction, a first cell via on the first bit line, a first dummy via on the first bit line and spaced apart from the first cell via in the second direction, an upper interlayer insulating film surrounding the first cell via and the first dummy via, a first upper bonding pad on the upper interlayer insulating film and connected to the first cell via, and a second upper bonding pad on the upper interlayer insulating film and not overlapping the first dummy via in the first direction.

According to some example embodiments of the present disclosure, an electronic system may include a main substrate, a semiconductor memory device including a cell structure on the main substrate and a peripheral circuit structure on the cell structure, and a controller on the main substrate and electrically connected to the semiconductor memory device, wherein the cell structure includes, a mold structure on a substrate and including a plurality of gate electrodes stacked and spaced apart from each other in a first direction, a channel structure penetrating through the mold structure and extending in the first direction, a bit line connected to the channel structure and extending in a second direction intersecting with the first direction, a cell via on the bit line, a dummy via on the bit line and spaced apart from the cell via in the second direction, an upper interlayer insulating film surrounding the cell via and the dummy via, a first upper bonding pad on the upper interlayer insulating film and connected to the cell via, and a second upper bonding pad on the upper interlayer insulating film and not overlapping the dummy via in the first direction, wherein the upper interlayer insulating film covers a lower surface of the dummy via.

According to some example embodiments of the present disclosure, a method of manufacturing a semiconductor memory device may include forming, on a substrate, a mold structure and a channel structure penetrating through the mold structure and extending in a first direction, forming a channel pad on the channel structure, forming a bit line contact on the channel pad, forming a bit line connected to the bit line contact and extending in a second direction intersecting with the first direction, forming a cell via and a dummy via on the bit line, and forming a first upper bonding pad and a second upper bonding pad, in which the cell via may be disposed to be spaced apart from the dummy via in the second direction, the first upper bonding pad may be connected to the cell via, and the second upper bonding pad may be disposed to be spaced apart from the dummy via.

According to some example embodiments, the cell via and the dummy via may be formed at the same time.

According to some example embodiments, the forming of the first upper bonding pad and the second upper bonding pad may include forming a first trench and a second trench on an upper interlayer insulating film covering the cell via and the dummy via, forming a first upper bonding pad in the first trench, and forming a second upper bonding pad in the second trench.

According to some example embodiments, the first trench may expose a portion of the cell via, and the second trench may be spaced apart from the dummy via.

According to some example embodiments, the first trench may expose a portion of the cell via, and one end of the cell via may protrude from a bottom surface of the first trench.

According to some example embodiments, the second upper bonding pad may not overlap the bit line in the first direction.

According to some example embodiments, the method of manufacturing the semiconductor memory device may further include coupling the first upper bonding pad and the first lower bonding pad and coupling the second upper bonding pad and the second lower bonding pad.

According to some example embodiments, the cell via and the dummy via may be disposed at the same vertical level.

According to some example embodiments, one end of the dummy via may overlap the second upper bonding pad in a third direction intersecting with the first and second directions, respectively.

According to some example embodiments, a width of the cell via in the second direction may be less than a width of the dummy via in the second direction.

According to some example embodiments, by disposing the dummy vias on the bit lines, the semiconductor memory device can relatively easily determine the location of a defective bit line.

### BRIEF DESCRIPTION OF THE DRAWINGS

The above and other example embodiments and features of the present disclosure will become more apparent by describing in detail some example embodiments thereof with reference to the attached drawings, in which:

FIG. 1 is an example plan view provided to explain a semiconductor memory device according to some example embodiments;

FIG. 2 is an example plan view provided to explain a semiconductor memory device according to some example embodiments;

FIG. 3 is a cross-sectional view taken along line A-A′ of FIGS. 1 and 2;

FIG. 4 is a cross-sectional view taken along line B-B′ of FIGS. 1 and 2;

FIG. 5 is an enlarged view provided to explain a region Q1 of FIG. 4;

FIGS. 6 and 7 are diagrams provided to explain a semiconductor memory device according to some example embodiments;

FIG. 8 is a diagram provided to explain a semiconductor memory device according to some example embodiments;

FIG. 9 is a diagram provided to explain a semiconductor memory device according to some example embodiments;

FIG. 10 is a diagram provided to explain a semiconductor memory device according to some example embodiments;

FIG. 11 is a diagram provided to explain a semiconductor memory device according to some example embodiments;

FIG. 12 is a diagram provided to explain a semiconductor memory device according to some example embodiments;

FIGS. 13 to 18 are diagrams showing intermediate stages, which are provided to explain a method of manufacturing a semiconductor memory device according to some example embodiments;

FIG. 19 is an example block diagram provided to explain an electronic system according to some example embodiments;

FIG. 20 is a perspective view provided as an example to explain an electronic system according to some example embodiments;

FIG. 21 is a schematic cross-sectional view taken along line V-V′ of FIG. 20.

### DETAILED DESCRIPTION

In the present disclosure, terms such as first, second, etc. may be used to describe various devices or components, but the devices or components are not limited by these terms. It should be understood that these terms are only used to distinguish one element or component from another element or component. It goes without saying that the first element or component mentioned below may be the second element or component within the technical idea of the present disclosure.

As used herein, expressions such as “one of,” “one or more of,” “any one of,” “at least one of,” and “at least one selected from” when preceding a list of elements, modify the entire list of elements and do not modify the individual elements of the list. Thus, for example, both “at least one of A, B, or C” and “at least one of A, B, and C” mean either A, B, C or any combination thereof. Likewise, A and/or B means A, B, or A and B.

While the term “same,” “equal” or “identical” is used in description of example embodiments, it should be understood that some imprecisions may exist. Thus, when one element is referred to as being the same as another element, it should be understood that an element or a value is the same as another element within a desired manufacturing or operational tolerance range (e.g., ±10%).

When the term “about,” “substantially” or “approximately” is used in this specification in connection with a numerical value, it is intended that the associated numerical value includes a manufacturing or operational tolerance (e.g., ±10%) around the stated numerical value. Moreover, when the word “about,” “substantially” or “approximately” is used in connection with geometric shapes, it is intended that precision of the geometric shape is not required but that latitude for the shape is within the scope of the disclosure. Further, regardless of whether numerical values or shapes are modified as “about” or “substantially,” it will be understood that these values and shapes should be construed as including a manufacturing or operational tolerance (e.g., ±10%) around the stated numerical values or shapes.

Semiconductor memory devices and electronic systems including the semiconductor memory device according to some example embodiments of the present disclosure will be described in detail with reference to the drawings.

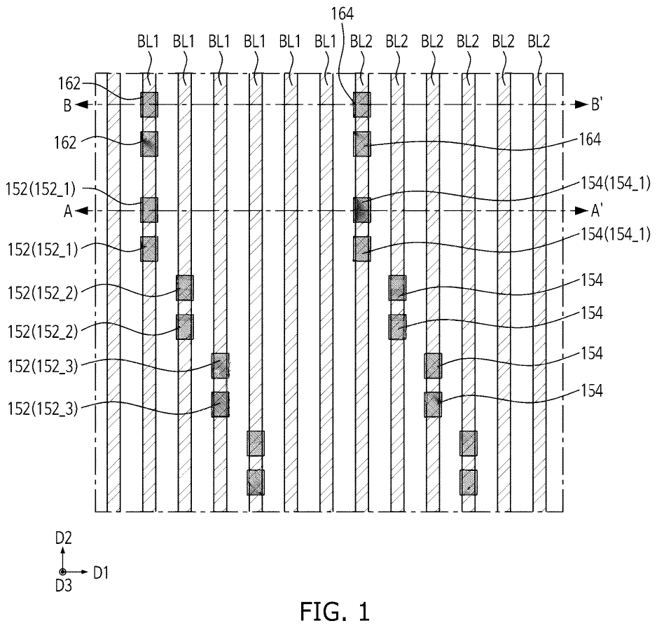

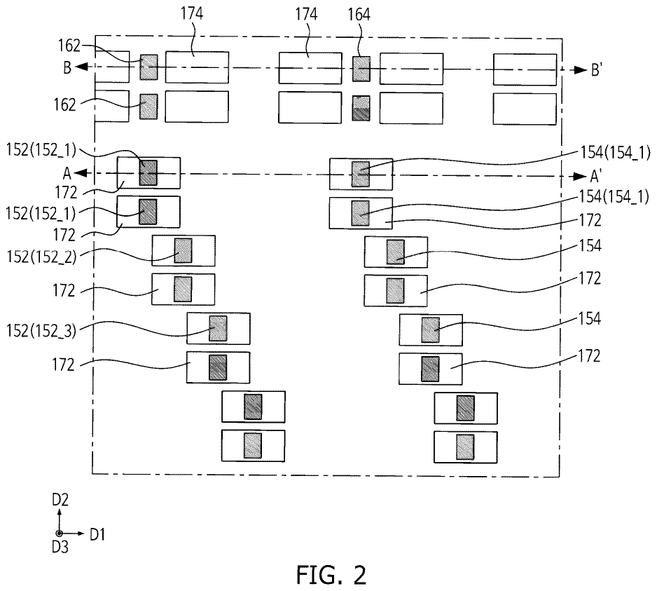

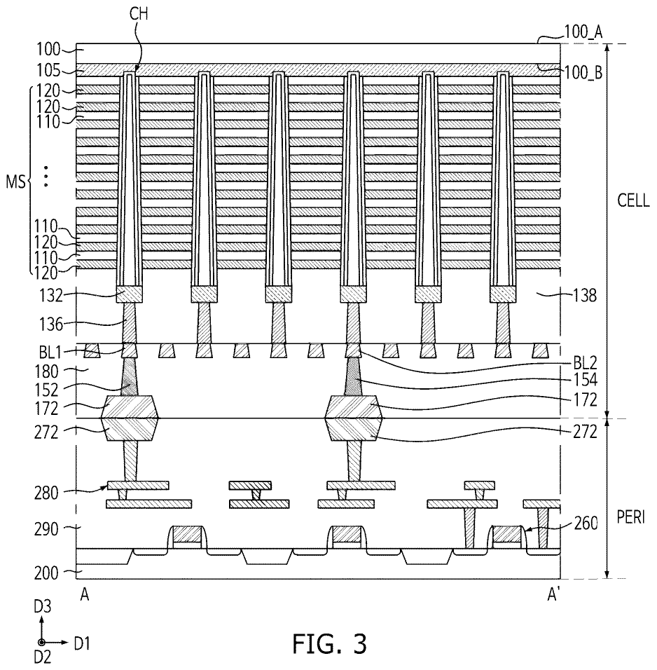

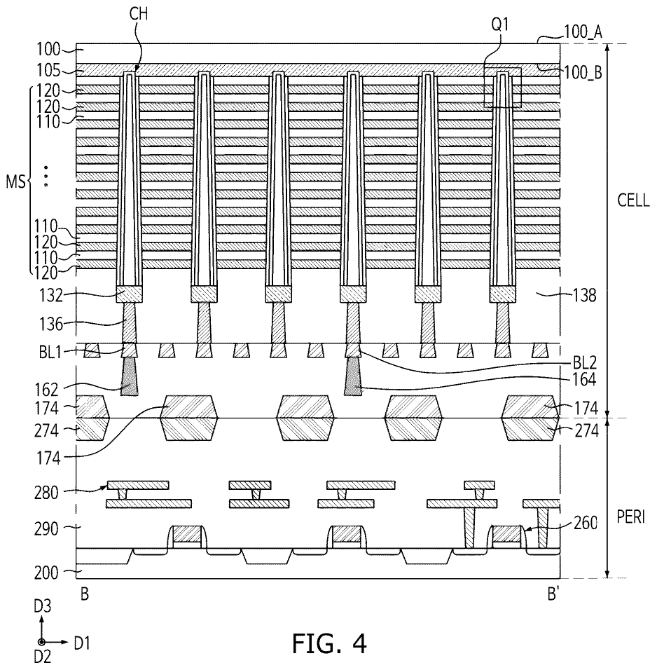

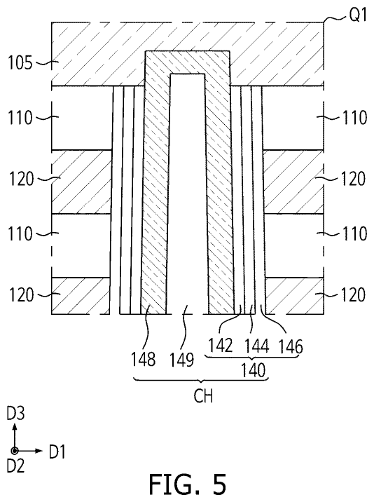

FIG. 1 is an example plan view provided to explain a semiconductor memory device according to some example embodiments. FIG. 2 is an example plan view provided to explain a semiconductor memory device according to some example embodiments. FIG. 3 is a cross-sectional view taken along line A-A′ of FIGS. 1 and 2. FIG. 4 is a cross-sectional view taken along line B-B′ of FIGS. 1 and 2. FIG. 5 is an enlarged view provided to explain a region Q1 of FIG. 4.

Referring to FIGS. 1 to 5, the semiconductor memory device according to some example embodiments may include a cell structure CELL and a peripheral circuit structure PERI.

The cell structure CELL may include a cell substrate 100, a common source plate 105, a mold structure MS, a channel structure CH, a channel pad 132, a bit line contact 136, a cell interlayer insulating film 138, a first bit line BL1, a second bit line BL2, a first cell via 152, a second cell via 154, a first dummy via 162, a second dummy via 164, a first upper bonding pad 172, a second upper bonding pad 174, and an upper interlayer insulating film 180.

For example, the cell substrate 100 may include a semiconductor substrate such as a silicon substrate, a germanium substrate, or a silicon-germanium substrate. In some example embodiments, the cell substrate 100 may include a Silicon-On-Insulator (SOI) substrate, a Germanium-On-Insulator (GOI) substrate, etc. In some example embodiments, the cell substrate 100 may include polysilicon (poly Si).

The cell substrate 100 may include a first surface 100_A and a second surface 100_B opposite to the first surface 100_A. The second surface 100_B of the cell substrate 100 may refer to a surface on which the mold structure MS and the channel structure CH are disposed. The first surface 100_A of the cell substrate 100 may be referred to as a back side of the cell substrate 100. The second surface 100_B of the cell substrate 100 may be referred to as a front side of the cell substrate 100.

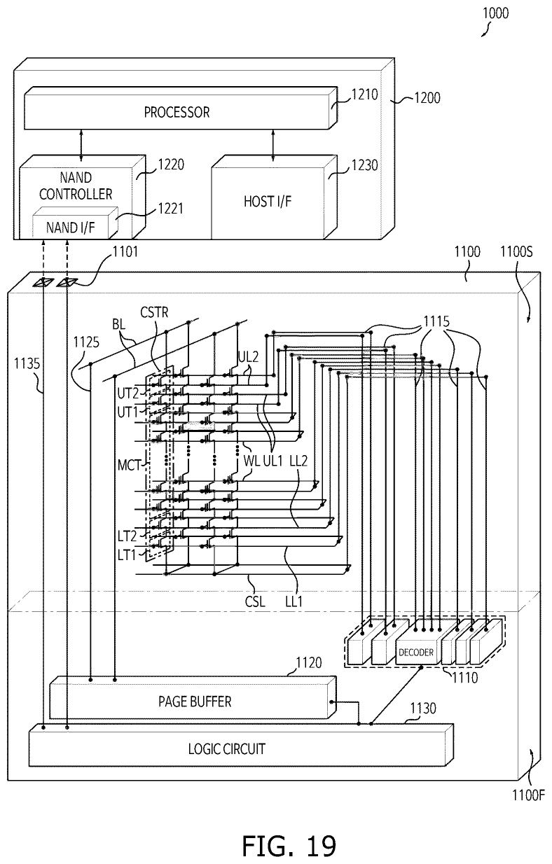

The common source plate 105 may be disposed on the second surface 100_B of the cell substrate 100. The common source plate 105 may be connected to the channel structure CH. For example, the common source plate 105 may be electrically connected to a semiconductor pattern 148 of the channel structure CH. The common source plate 105 may be provided as a common source line (e.g., CSL of FIG. 19) of the semiconductor memory device. For example, the common source plate 105 may include polycrystalline silicon or metal doped with an impurity, but example embodiments are not limited thereto.

The mold structure MS may be disposed on the common source plate 105. The mold structure MS may be disposed on the second surface 100_B of the cell substrate 100. The mold structure MS may include a plurality of mold insulating layers 110 and a plurality of gate electrodes 120 alternately stacked in a third direction D3. Each of the mold insulating layers 110 and each of the gate electrodes 120 may have a layered structure extending parallel to the second surface 100_B of the cell substrate 100. The gate electrodes 120 may be sequentially stacked on the common source plate 105 and spaced apart from each other by the mold insulating layers 110.

In some example embodiments, some of the plurality of gate electrodes 120 may be provided as a ground select line GSL of the semiconductor memory device. Some other ones of the plurality of gate electrodes 120 of the plurality of gate electrodes 120 may be provided as a string select line SSL of the semiconductor memory device. For example, the gate electrode 120, of the plurality of gate electrodes 120, which is adjacent to the common source plate 105 may be provided as the ground select line GSL. The gate electrode 120, of the plurality of gate electrodes 120, which is adjacent to the bit lines BL1 and BL2 may be provided as the string select line SSL. However, example embodiments are not limited to the above. The arrangement and/or the number of the ground select lines GSL and/or the string select lines SSL may vary.

In some example embodiments, some of the plurality of gate electrodes 120 may be used as an erase control line (ECL) of the semiconductor memory device. The erase control line ECL may be used as a gate electrode of an erase transistor. The erase transistor may generate a Gate Induced Drain Leakage (GIDL) to perform an erase operation of a plurality of memory cell transistors.

Although not illustrated, in some example embodiments, the plurality of gate electrodes 120 may extend in a first direction D1 and may be disposed on an extended region of the cell substrate 100. Each of the plurality of gate electrodes 120 may extend to different lengths to form a stepped structure having a staircase shape. By the stepped structure, a specific gate electrode 120 may include an end portion exposed by the gate electrode 120 disposed above the specific gate electrode 120. A word line contact may be formed on the end portion of the gate electrode 120.

Each of the gate electrodes 120 may include a conductive material, for example, a metal such as tungsten (W), cobalt (Co), and nickel (Ni), or a semiconductor material such as silicon, but example embodiments are not limited thereto.

The mold insulation layer 110 may include an insulation material. For example, the mold insulation layer 110 may include at least one of silicon oxide, silicon nitride, or silicon oxynitride, but example embodiments are not limited thereto.

The channel structure CH may be disposed on the cell substrate 100. The channel structure CH may be penetrating through the mold structure MS and extend in the third direction D3. For example, the channel structure CH may be penetrating through each of the plurality of mold insulating layers 110 and the plurality of gate electrodes 120. The channel structure CH may intersect with the plurality of gate electrodes 120. The channel structure CH may be disposed in a channel hole extending in the third direction D3. The channel structure CH may have a pillar shape (e.g., a cylindrical shape) extending in the third direction D3.

In some example embodiments, due to a high aspect ratio of the mold structure MS, a cross-section of the channel structure CH may have an inclined side surface with a width that decreases towards the cell substrate 100. However, example embodiments are not limited to the above.

The channel structure CH may include an information storage film 140, the semiconductor pattern 148, and a filling pattern 149.

The semiconductor pattern 148 may extend in the third direction D3 and penetrate through the mold structure MS. One end of the semiconductor pattern 148 may be penetrating through a lower surface of the common source plate 105. One end of the semiconductor pattern 148 may be disposed in the common source plate 105. Although it is illustrated that the semiconductor pattern 148 has a cup shape, example embodiments are not limited thereto. For example, the semiconductor pattern 148 may have various shapes such as a cylindrical shape, a rectangular cylindrical shape, a solid pillar shape, etc. For example, the semiconductor pattern 148 may include a semiconductor material such as a single crystal silicon, a polycrystalline silicon, an organic semiconductor material, and a carbon nanostructure, but example embodiments are not limited thereto.

The information storage film 140 may be interposed between the semiconductor pattern 148 and the gate electrode 120 and between the semiconductor pattern 148 and the mold insulating layer 110. For example, the information storage film 140 may extend along an outer surface of the semiconductor pattern 148. For example, the information storage film 140 may include at least one of silicon oxide, silicon nitride, silicon oxynitride, or a high-k material having a higher dielectric constant than the silicon oxide. For example, the high-k material may include at least one of aluminum oxide, hafnium oxide, lanthanum oxide, tantalum oxide, titanium oxide, lanthanum hafnium oxide, lanthanum aluminum oxide, dysprosium scandium oxide, or a combination thereof.

In some example embodiments, from a planar perspective, the channel structures CH may be arranged in a zigzag pattern. For example, the channel structures CH may be arranged in a staggered manner in the first direction D1 and a second direction D2. The channel structures CH disposed in the zigzag pattern may further improve the integration density of the semiconductor memory device. In some example embodiments, the channel structures CH may be arranged in a honeycomb pattern.

In some example embodiments, the information storage film 140 may include multiple films. The information storage film 140 may include a tunnel insulating film 142, a charge storage film 144, and a blocking insulating film 146, which may be stacked in order on the outer surface of the semiconductor pattern 148.

For example, the tunnel insulating film 142 may include the silicon oxide or a high-k material (e.g., aluminum oxide (Al₂O₃) or hafnium oxide (HfO₂)) having a higher dielectric constant than the silicon oxide. For example, the charge storage film 144 may include silicon nitride. For example, the blocking insulating film 146 may include the silicon oxide or a high-k material (e.g., aluminum oxide (Al₂O₃) or hafnium oxide (HfO₂)) having a higher dielectric constant than the silicon oxide.

In some example embodiments, the channel structure CH may further include the filling pattern 149. The filling pattern 149 may fill the interior of the semiconductor pattern 148 in the cup shape. For example, the filling pattern 149 may include an insulating material such as silicon oxide, but example embodiments are not limited thereto.

The channel pad 132 may be disposed on the channel structure CH. The channel pad 132 may be disposed on the channel structure CH and electrically connected to the semiconductor pattern 148. The bit line contact 136 may be disposed on the channel pad 132.

For example, the channel pad 132 may include polysilicon doped with an impurity, but example embodiments are not limited thereto. The bit line contact 136 may include, for example, a conductive material such as tungsten (W), copper (Cu), aluminum (Al), and molybdenum (Mo).

The cell interlayer insulating film 138 may cover the mold structure MS and the channel structure CH. The bit line contact 136 may be disposed in the cell interlayer insulating film 138. The bit lines BL1 and BL2 may be disposed on a lower surface of the cell interlayer insulating film 138. For example, the cell interlayer insulation film 138 may include at least one of silicon oxide, silicon oxynitride, or a low-k material having a lower dielectric constant than silicon oxide, but example embodiments are not limited thereto.

A plurality of first bit lines BL1 may be disposed in the upper interlayer insulating film 180. The plurality of first bit lines BL1 may be disposed on the bit line contact 136. Each of the plurality of first bit lines BL1 may be connected to the channel structure CH through the bit line contact 136. Each of the plurality of first bit lines BL1 may extend in the second direction D2. The plurality of first bit lines BL1 may be spaced apart from each other in the first direction D1. The plurality of first bit lines BL1 may be spaced apart from each other at regular intervals in the first direction D1.

A plurality of first cell vias 152 may be disposed in the upper interlayer insulating film 180. The plurality of first cell vias 152 may be disposed on the plurality of first bit lines BL1. For example, two first cell vias 152 may be disposed on one first bit line BL1. However, example embodiments are not limited to the above. For example, one first cell via 152 may be disposed on one first bit line BL1, or three or more first cell vias 152 may be disposed. Hereinafter, it will be assumed that a pair of first cell vias 152 are disposed on one first bit line BL1. The first cell vias 152 may be spaced apart from each other in the second direction D2 on one first bit line BL1.

The pair of first cell vias 152 may be spaced apart from each other in the first direction D1 and the second direction D2. For example, a pair of first cell vias 152_1 disposed on the first bit line BL1 may be spaced apart from an adjacent pair of first cell vias 152_2 disposed on the first bit line BL1 in the first direction D1, in the first and second directions D1 and D2. Likewise, the pair of first cell vias 152_2 disposed on the first bit line BL1 may be spaced apart from an adjacent pair of first cell vias 152_3 disposed on the first bit line BL1 in the first direction D1, in the first and second directions D1 and D2.

The first dummy via 162 may be disposed in the upper interlayer insulating film 180. The first dummy via 162 may be disposed on the first bit line BL1. An upper surface of the first dummy via 162 may be in contact with the first bit line BL1. The first dummy via 162 may be disposed only on some of the plurality of first bit lines BL1. For example, the first dummy via 162 may be disposed on the first bit line BL1 to be connected to the first cell via 152_1 and may not be disposed on the remaining first bit lines BL1. The first dummy via 162 may be spaced apart from the first cell via 152 in the second direction D2.

The first dummy via 162 may be spaced apart from the second upper bonding pad 174. For example, from a planar perspective, the first dummy via 162 may be spaced apart from the second upper bonding pad 174 in the first direction D1. The first dummy via 162 may be disposed between the second upper bonding pads 174. For example, the first dummy via 162 may be disposed between a second upper bonding pad 174 and another second upper bonding pad 174 adjacent thereto in the first direction D1. The first dummy via 162 may not overlap the second upper bonding pad 174 in the third direction D3. The first dummy via 162 may not be connected to (e.g., not in physical contact with) the second upper bonding pad 174. The upper interlayer insulating film 180 may be disposed between the first dummy via 162 and the second upper bonding pad 174. The upper interlayer insulating film 180 may cover a lower surface of the first dummy via 162.

In some example embodiments, a width of the first cell via 152 in the first direction D1 may be greater than a width of the first bit line BL1 in the first direction D1. A width of the first dummy via 162 in the first direction D1 may be greater than the width of the first bit line BL1 in the first direction D1. However, example embodiments are not limited to the above.

In some example embodiments, the first cell via 152 and the first dummy via 162 may have the same shape. For example, the widths of the first cell via 152 and the first dummy via 162 in the first direction D1 and their widths in the second direction D2 may be identical, respectively. In addition, a height of the first cell via 152 in the third direction D3 and a height of the first dummy via 162 in the third direction D3 may be the same. In other words, a distance from a lower surface of the first bit line BL1 to a lower surface of the first cell via 152 may be the same as a distance from the lower surface of the first bit line BL1 to the lower surface of the first dummy via 162. In some example embodiments, the lower surface of the first cell via 152 and the lower surface of the first dummy via 162 may be disposed on the same plane.

In some example embodiments, two first dummy vias 162 may be disposed on the first bit line BL1. The first dummy vias 162 may be spaced apart from each other in the second direction D2. In some example embodiments, an interval between the first dummy via 162 and an adjacent first dummy via 162 in the second direction D2 may be the same as an interval between the first cell via 152_1 and an adjacent first cell via 152_1 in the second direction D2. However, example embodiments are not limited to the above.

A plurality of second bit lines BL2 may be disposed in the upper interlayer insulating film 180. The plurality of second bit lines BL2 may be disposed on the bit line contact 136. Each of the plurality of second bit lines BL2 may be connected to the channel structure CH through the bit line contact 136. Each of the plurality of second bit lines BL2 may extend in the second direction D2. The plurality of second bit lines BL2 may be spaced apart from each other in the first direction D1. The plurality of second bit lines BL2 may be spaced apart from each other at regular intervals in the first direction D1.

The plurality of second bit lines BL2 may be spaced apart from the plurality of first bit lines BL1 in the first direction D1. For example, the bit lines BL1 and BL2 may be aligned in the first direction D1. In some example embodiments, the number of first bit lines BL1 may be the same as the number of second bit lines BL2.

A plurality of second cell vias 154 may be disposed in the upper interlayer insulating film 180. The plurality of second cell vias 154 may be disposed on the plurality of second bit lines BL2. For example, two second cell vias 154 may be disposed on one second bit line BL2. However, example embodiments are not limited to the above. The pair of second cell vias 154 may be disposed to be spaced apart from each other in the second direction D2.

The second dummy via 164 may be disposed in the upper interlayer insulating film 180. The second dummy via 164 may be disposed on the second bit line BL2. The second dummy via 164 may be disposed only on some of the plurality of second bit lines BL2. For example, the second dummy via 164 may be disposed on one second bit line BL2 to be connected to a first cell via 154_1 and may not be disposed on the remaining second bit lines BL2. The second dummy via 164 may be spaced apart from the second cell via 154 in the second direction D2.

The second dummy via 164 may be spaced apart from the second upper bonding pad 174. For example, from a planar perspective, the second dummy via 164 may be spaced apart from the second upper bonding pad 174 in the first direction D1. The second dummy via 164 may be disposed between the second upper bonding pads 174. For example, the second dummy via 164 may be disposed between a second upper bonding pad 174 and another second upper bonding pad 174 adjacent thereto in the first direction D1. The second dummy via 164 may not overlap the second upper bonding pad 174 in the third direction D3. The second dummy via 164 may not be connected to (e.g., not in physical contact with) the second upper bonding pad 174. The upper interlayer insulating film 180 may be disposed between the second dummy via 164 and the second upper bonding pad 174. The upper interlayer insulating film 180 may cover a lower surface of the second dummy via 164.

In some example embodiments, a width of the second cell via 154 in the first direction D1 may be greater than a width of the second bit line BL2 in the first direction D1. A width of the second dummy via 164 in the first direction D1 may be greater than the width of the second bit line BL2 in the first direction D1. However, example embodiments are not limited to the above.

In some example embodiments, the second cell via 154 and the second dummy via 164 may have the same shape. For example, the widths of the second cell vias 154 and the second dummy vias 164 in the first direction D1 and the widths in the second direction D2 may be identical, respectively. In addition, a height of the second cell via 154 in the third direction D3 and a height of the second dummy via 164 in the third direction D3 may be the same. In other words, a distance from the lower surface of the second bit line BL2 to a lower surface of the second cell via 154 may be the same as a distance from the lower surface of the second bit line BL2 to the lower surface of the second dummy via 164. In some example embodiments, the lower surface of the second cell via 154 and the lower surface of the second dummy via 164 may be disposed on the same plane.

The cell vias 152 and 154 may be disposed with a certain periodicity. For example, an arrangement relationship between the plurality of second cell vias 154 and the plurality of second bit lines BL2 may be the same as an arrangement relationship between the plurality of first cell vias 152 and the plurality of first bit lines BL1. The plurality of first bit lines BL1 may be disposed between a first bit line BL1 on which the first dummy via 162 is disposed and the second bit line BL2 on which the second dummy via 164 is disposed. It is illustrated that the number of the first bit lines BL1 is six, but this should be interpreted as an example. The number of first bit lines BL1 may be several hundred or several thousand or more. The first cell via 152 may overlap the second cell via 154 in the first direction D1. In addition, the first dummy via 162 may overlap the second dummy via 164 in the first direction D1.

The semiconductor memory device may include tens of thousands of bit lines or more. For defect inspection of a semiconductor memory device, a reference point may be needed for reading a location value of a specific bit line. According to some example embodiments, the semiconductor memory device includes the first dummy via 162 and the second dummy via 164, enabling relatively easy identification of the locations of specific bit lines BL1 and BL2. For example, the first dummy via 162 may be used as a reference point for the plurality of first bit lines BL1, and the second dummy via 164 may be used as a reference point for the plurality of second bit lines BL2. By using the first dummy via 162 and the second dummy via 164 as reference points, the location of the bit line where the defect occurred may be relatively easily identified.

The upper interlayer insulating film 180 may be disposed on the cell interlayer insulating film 138. The upper interlayer insulating film 180 may surround the first bit line BL1, the second bit line BL2, the first cell via 152, the second cell via 154, the first dummy via 162, and the second dummy via 164. For example, the upper interlayer insulating film 180 may include at least one of silicon oxide, silicon oxynitride, or a low-k material having a lower dielectric constant than silicon oxide, but example embodiments are not limited thereto.

The first upper bonding pad 172 may be disposed on each of the first cell via 152 and the second cell via 154. The first upper bonding pad 172 may be connected to each of the first cell via 152 and the second cell via 154. The first upper bonding pad 172 may be disposed on the upper interlayer insulating film 180. For example, the first upper bonding pad 172 may be disposed on a first trench formed on the upper interlayer insulating film 180. The upper interlayer insulating film 180 may surround an upper surface and side surfaces of the first upper bonding pad 172. In some example embodiments, a lower surface of the first upper bonding pad 172 and a lower surface of the upper interlayer insulating film 180 may be disposed on the same plane.

The second upper bonding pad 174 may be disposed on the upper interlayer insulating film 180. For example, the second upper bonding pad 174 may be disposed on a second trench formed on the upper interlayer insulating film 180. The upper interlayer insulating film 180 may surround an upper surface and side surfaces of the second upper bonding pad 174. In some example embodiments, a lower surface of the second upper bonding pad 174 and a lower surface of the upper interlayer insulating film 180 may be disposed on the same plane.

The second upper bonding pad 174 may not overlap some (two or more) of the plurality of first bit lines BL1 in the third direction D3. For example, the second upper bonding pad 174 may not overlap in the third direction D3 the first bit line BL1 on which the first dummy via 162 is disposed. The second upper bonding pad 174 may not overlap some of the plurality of second bit lines BL2 in the third direction D3. For example, the second upper bonding pad 174 may not overlap in the third direction D3 the second bit line BL2 on which the second dummy via 164 is disposed.

In some example embodiments, the first upper bonding pad 172 and the second upper bonding pad 174 may be disposed at the same vertical level. For example, the lower surface of the first upper bonding pad 172 and the lower surface of the second upper bonding pad 174 may be disposed on the same plane.

A first lower bonding pad 272 may be disposed below the first upper bonding pad 172. An upper surface of the first lower bonding pad 272 may be in contact with the lower surface of the first upper bonding pad 172. The first lower bonding pad 272 may be connected to the first upper bonding pad 172. The first lower bonding pad 272 may be disposed on a peripheral circuit insulating film 290. The peripheral circuit insulating film 290 may surround a lower surface and side surfaces of the first lower bonding pad 272.

A second lower bonding pad 274 may be disposed below the second upper bonding pad 174. An upper surface of the second lower bonding pad 274 may be in contact with the lower surface of the second upper bonding pad 174. The second lower bonding pad 274 may be connected to the second upper bonding pad 174. The second lower bonding pad 274 may be disposed on the peripheral circuit insulating film 290. The peripheral circuit insulating film 290 may surround a lower surface and side surfaces of the second lower bonding pad 274. In some example embodiments, the first lower bonding pad 272 and the second lower bonding pad 274 may be disposed at the same vertical level. For example, the upper surface of the first lower bonding pad 272 and a lower surface of the second lower bonding pad 274 may be disposed on the same plane.

The upper bonding pads 172 and 174 and the lower bonding pads 272 and 274 may each include, for example, conductive metal. The upper bonding pads 172 and 174 and the lower bonding pads 272 and 274 may each include any one of, for example, copper (Cu), aluminum (Al), cobalt (Co), tungsten (W), or molybdenum (Mo).

The first upper bonding pad 172 may be connected to the first lower bonding pad 272, and the second upper bonding pad 174 may be connected to the second lower bonding pad 274. For example, the first upper bonding pad 172 may be coupled to be in contact with the first lower bonding pad 272 by copper-to-copper bonding. Likewise, the second upper bonding pad 174 may be coupled to the second lower bonding pad 274 by the copper-to-copper bonding. The upper bonding pads 172 and 174 and the lower bonding pads 272 and 274 may be provided as an electrical connection path between the cell structure CELL and the peripheral circuit structure PERI.

The peripheral circuit structure PERI may include a peripheral circuit substrate 200, a peripheral circuit element 260, the lower bonding pads 272 and 274, and a peripheral circuit wiring structure 280.

For example, the peripheral circuit substrate 200 may include a semiconductor substrate such as a silicon substrate, a germanium substrate, or a silicon-germanium substrate. In some example embodiments, a peripheral circuit substrate 300 may also include a silicon-on-insulator (SOI) substrate or a germanium-on-insulator (GOI) substrate.

The peripheral circuit element 260 may be formed on the peripheral circuit substrate 200. The peripheral circuit element 260 may configure a peripheral circuit that controls the operation of the semiconductor memory device. For example, the peripheral circuit element 260 may include a logic circuit 1130, a page buffer 1120, a decoder 1110, etc. of FIG. 19. In the following description, the surface of the peripheral circuit substrate 200 where the peripheral circuit element 260 is disposed may be referred to as a front side of the peripheral circuit substrate 200. Conversely, the surface of the peripheral circuit substrate 200 opposite to the front side of the peripheral circuit substrate 200 may be referred to as a back side of the peripheral circuit substrate 200.

For example, the peripheral circuit element 260 may include a transistor, but example embodiments are not limited thereto. For example, the peripheral circuit element 260 may include not only various active elements such as transistors, but also various passive elements such as capacitors, registers, or inductors.

The peripheral circuit wiring structure 280 may be formed on the peripheral circuit element 260. For example, a peripheral circuit insulating film 290 may be formed on the front side of the peripheral circuit substrate 200, and the peripheral circuit wiring structure 280 may be formed in the peripheral circuit insulating film 290. The peripheral circuit wiring structure 280 may be electrically connected to the peripheral circuit element 260. The number, arrangement, etc. of the layers of the peripheral circuit wiring structure 280 illustrated herein are merely examples, and example embodiments are not limited thereto.

In some example embodiments, the cell structure CELL may be stacked on the peripheral circuit structure PERI. For example, the cell structure CELL may be stacked on the peripheral circuit insulating film 290. The semiconductor memory device according to some example embodiments may have a chip-to-chip (C2C) structure. The C2C structure refers to manufacturing an upper chip including the cell structure CELL on a first wafer (e.g., the cell substrate 100), manufacturing a lower chip including the peripheral circuit structure PERI on a second wafer (e.g., the peripheral circuit substrate 300) that is different from the first wafer, and connecting the upper and lower chips to each other by a bonding method.

In some example embodiments, the bonding method may refer to a method of electrically connecting the first upper bonding pads 172 and 174 formed on the uppermost metal layer of the upper chip and the lower bonding pads 272 and 274 formed on the uppermost metal layer of the lower chip to each other. For example, if the upper bonding pads 172 and 174 and the lower bonding pads 272 and 274 are formed of copper (Cu), the bonding method may be the copper-to-copper (Cu—Cu) bonding method described above.

The bit lines BL1 and BL2 and/or each of the gate electrodes 120 may be electrically connected to the peripheral circuit element 260 as the upper bonding pads 172 and 174 and the lower bonding pads 272 and 274 are bonded.

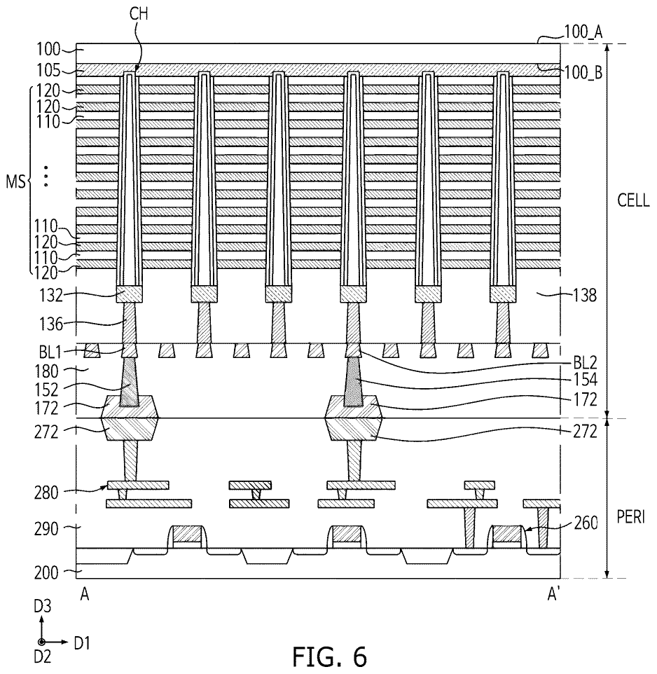

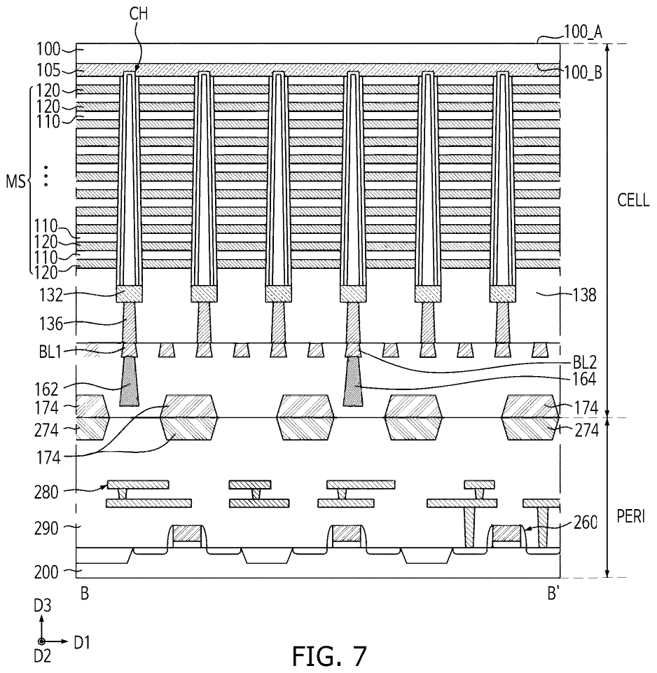

FIGS. 6 and 7 are diagrams provided to explain a semiconductor memory device according to some example embodiments. For reference, FIG. 6 may correspond to a cross-sectional view taken along line A-A′ of FIGS. 1 and 2, and FIG. 7 may correspond to a cross-sectional view taken along line B-B′ of FIGS. 1 and 2. For convenience of description, different configurations from those described in FIGS. 1 to 5 will be primarily described.

Referring to FIGS. 6 and 7, in the semiconductor memory device according to some example embodiments, one end of the first cell via 152 may be disposed in the first upper bonding pad 172. The lower surface of the first cell via 152 may be disposed in the first upper bonding pad 172. The first cell via 152 may penetrate through an upper surface of the first upper bonding pad 172.

One end of the second cell via 154 may be disposed in the first upper bonding pad 172. The lower surface of the second cell via 154 may be disposed in the first upper bonding pad 172. The second cell via 154 may penetrate through the upper surface of the first upper bonding pad 172.

The second cell via 154 may be disposed at the same vertical level as the first cell via 152. For example, the lower surface of the first cell via 152 and the lower surface of the second cell via 154 may be disposed at the same vertical level. In some example embodiments, the lower surface of the first cell via 152 and the lower surface of the second cell via 154 may be disposed on the same plane.

One end of the first dummy via 162 may be disposed between the second upper bonding pads 174. The upper interlayer insulating film 180 may cover the lower surface of the first dummy via 162. One end of the first dummy via 162 may overlap the second upper bonding pad 174 in the first direction D1. The lower surface of the first dummy via 162 may be disposed at a lower vertical level than an upper surface of the second upper bonding pad 174. For example, a distance from the lower surface of the cell interlayer insulating film 138 to the lower surface of the first dummy via 162 may be greater than a distance from the lower surface of the cell interlayer insulating film 138 to the upper surface of the second upper bonding pad 174.

One end of the second dummy via 164 may be disposed between the second upper bonding pads 174. The upper interlayer insulating film 180 may cover the lower surface of the second dummy via 164. One end of the second dummy via 164 may overlap the second upper bonding pad 174 in the first direction D1. The lower surface of the second dummy via 164 may be disposed at a lower vertical level than the upper surface of the second upper bonding pad 174. For example, a distance from the lower surface of the cell interlayer insulating film 138 to the lower surface of the second dummy via 164 may be greater than a distance from the lower surface of the cell interlayer insulating film 138 to the upper surface of the second upper bonding pad 174.

In some example embodiments, the lower surface of the first cell via 152, the lower surface of the second cell via 154, the lower surface of the first dummy via 162 and the lower surface of the second dummy via 164 may be disposed on the same plane. However, example embodiments are not limited to the above.

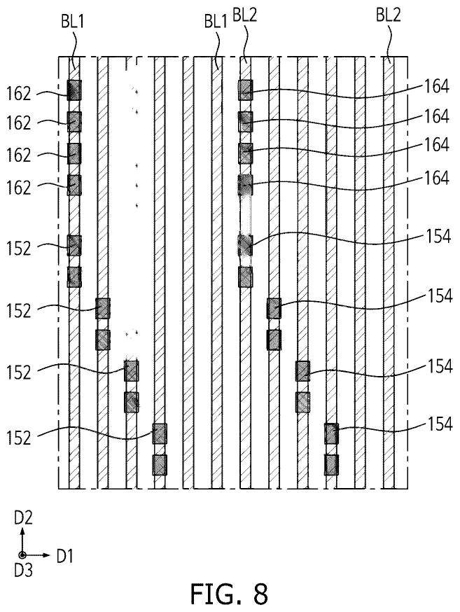

FIG. 8 is a diagram provided to explain a semiconductor memory device according to some example embodiments. For convenience of description, different configurations from those described in FIGS. 1 to 5 will be primarily described.

Referring to FIG. 8, in the semiconductor memory device according to some example embodiments, a plurality of first dummy vias 162 may be disposed on the first bit line BL1. The number of first dummy vias 162 disposed on the first bit line BL1 may be four. The first dummy vias 162 may be disposed to be spaced apart from each other in the second direction D2. In some example embodiments, the first dummy vias 162 may be aligned at regular intervals. However, example embodiments are not limited to the above.

Like the first dummy via 162, a plurality of second dummy vias 164 may be disposed on the second bit line BL2. The number of first dummy vias 164 disposed on the second bit line BL2 may be four. The second dummy vias 164 may be disposed to be spaced apart from each other in the second direction D2. In some example embodiments, the second dummy vias 164 may be aligned at regular intervals. However, example embodiments are not limited to the above.

The number of dummy vias 162 and 164 may be different from the number of cell vias 152 and 154. For example, the number of dummy vias 162 and 164 disposed on one bit line BL1 and BL2 may be four, and the number of cell vias 152 and 154 may be two.

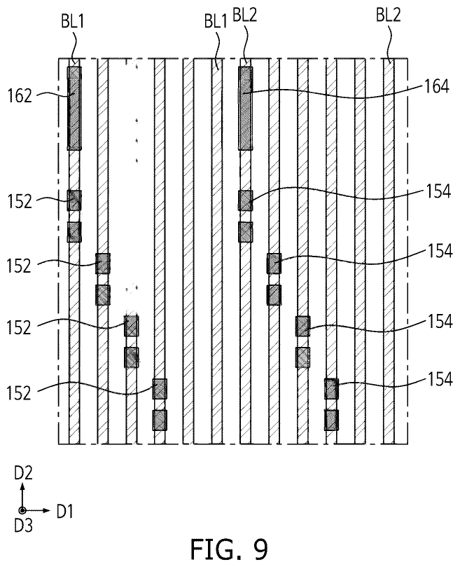

FIG. 9 is a diagram provided to explain a semiconductor memory device according to some example embodiments. For convenience of description, different configurations from those described in FIGS. 1 to 5 will be primarily described.

Referring to FIG. 9, in the semiconductor memory device according to some example embodiments, the first dummy via 162 may be disposed on the first bit line BL1. The first dummy via 162 may extend in the second direction D2.

In some example embodiments, the shape of the first dummy via 162 may be different from the shape of the first cell via 152. For example, a width of the first dummy via 162 in the second direction D2 may be greater than a width of the first cell via 152 in the second direction D2. Although it is illustrated that the width of the first dummy via 162 in the first direction D1 and the width of the first cell via 152 in the first direction D1 are the same, example embodiments are not limited thereto. For example, the width of the first dummy via 162 in the first direction D1 may be different from the width of the first cell via 152 in the first direction D1.

In some example embodiments, a shape of the second dummy via 164 may be different from a shape of the second cell via 154. For example, a width of the second dummy via 164 in the second direction D2 may be greater than a width of the second cell via 154 in the second direction D2. Although it is illustrated that the width of the second dummy via 164 in the first direction D1 and the width of the second cell via 154 in the first direction D1 are the same, example embodiments are not limited thereto. For example, the width of the second dummy via 164 in the first direction D1 may be different from the width of the second cell via 154 in the first direction D1.

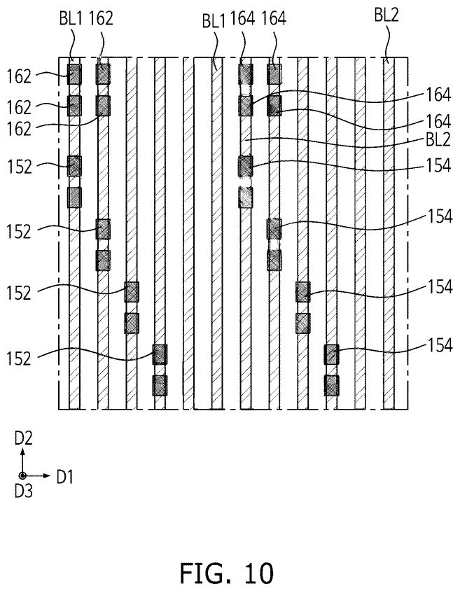

FIG. 10 is a diagram provided to explain a semiconductor memory device according to some example embodiments. For convenience of description, different configurations from those described in FIGS. 1 to 5 will be primarily described.

Referring to FIG. 10, in the semiconductor memory device according to some example embodiments, the first dummy via 162 may be disposed on some (e.g., two or more) of the plurality of first bit lines BL1. For example, the first dummy via 162 may be disposed on two first bit lines BL1 of the first bit lines BL1. The first dummy via 162 may be disposed on one first bit line BL1 and another bit line BL1 adjacent to the one first bit line BL1 in the first direction D1. The first dummy via 162 and the adjacent first dummy via 162 in the first direction D1 may overlap each other in the first direction D1.

The second dummy via 164 may be disposed on some (e.g., two or more) of the plurality of second bit lines BL2. For example, the second dummy via 164 may be disposed on two second bit lines BL2. The second dummy via 164 may be disposed on one second bit line BL2 and another second bit line BL2 adjacent to the one second bit line BL2 in the first direction D1. The second dummy via 164 and the adjacent second dummy via 164 in the first direction D1 may overlap each other in the first direction D1.

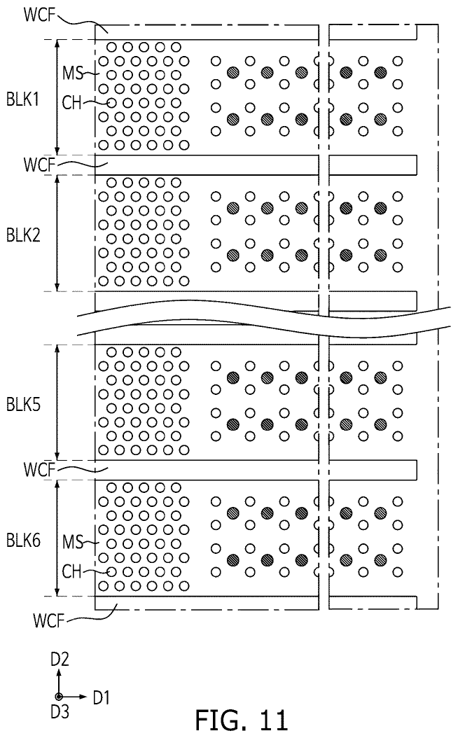

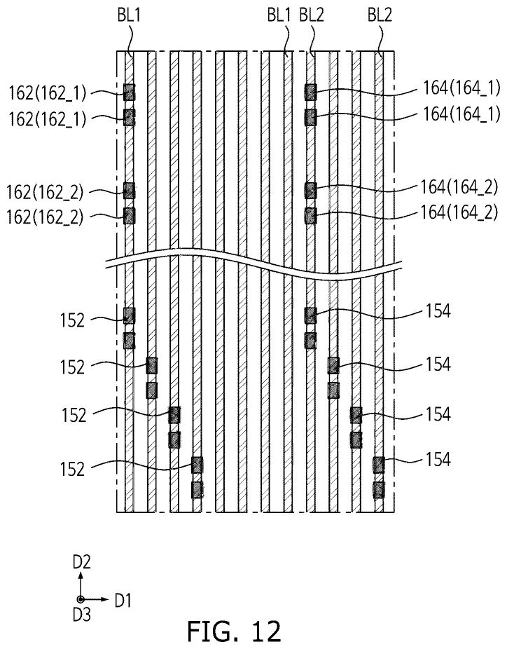

FIG. 11 is a diagram provided to explain a semiconductor memory device according to some example embodiments. FIG. 12 is a diagram provided to explain a semiconductor memory device according to some example embodiments. For convenience of description, different configurations from those described in FIGS. 1 to 5 will be primarily described.

Referring to FIG. 11, the semiconductor memory device according to some example embodiments may further include a word line separation structure WCF. The word line separation structure WCF may extend in the first direction D1. The word line separation structure WCF may separate the mold structure MS. The mold structure MS may be divided by the word line separation structure WCF to form cell blocks (e.g., BLK1, BLK2, BLK5, BLK6). For example, the word line separation structure WCF may be disposed between a first cell block BLK1 and a second cell block BLK2.

Referring to FIGS. 11 and 12, in the semiconductor device according to some example embodiments, the plurality of first dummy vias 162 may include a pair of first sub dummy vias 162_1 and a pair of second sub dummy vias 162_2. The pair of first sub dummy vias 162_1 and the pair of second sub dummy vias 162_2 may be disposed on one first bit line BL1. The pair of first sub dummy vias 162_1 may be disposed to be spaced apart from the pair of second sub dummy vias 162_2 in the second direction D2.

The plurality of second dummy vias 164 may include a pair of third sub dummy vias 164_1 and a pair of fourth sub dummy vias 164_2. The pair of third sub dummy vias 164_1 and the pair of fourth sub dummy vias 164_2 may be disposed on one second bit line BL2. The pair of third sub dummy vias 164_1 may be disposed to be spaced apart from the pair of fourth sub dummy vias 164_2 in the second direction D2.

In some example embodiments, a plurality of cell blocks may be disposed between the first sub dummy via 162_1 and the second sub dummy via 162_2. For example, the first sub dummy via 162_1 may be disposed on the first cell block BLK1. The first sub dummy via 162_1 may be used as a reference point indicating the location of the first cell block BLK1. The second sub dummy via 162_2 may be disposed on the fifth cell block BLK5. The second sub dummy via 162_2 may be used as a reference point indicating the location of the fifth cell block BLK5. The second cell block BLK2, a third cell block, and a fourth cell block may be disposed between the first sub dummy via 162_1 and the second sub dummy via 162_2. However, example embodiments are not limited to the above. The number of cell blocks disposed between the first sub dummy via 162_1 and the second sub dummy via 162_2 may vary. By disposing the first sub dummy via 162_1 and the second sub dummy via 162_2 at regular intervals in the second direction D2, it is possible to relatively easily identify a cell block in which a specific channel structure CH is disposed.

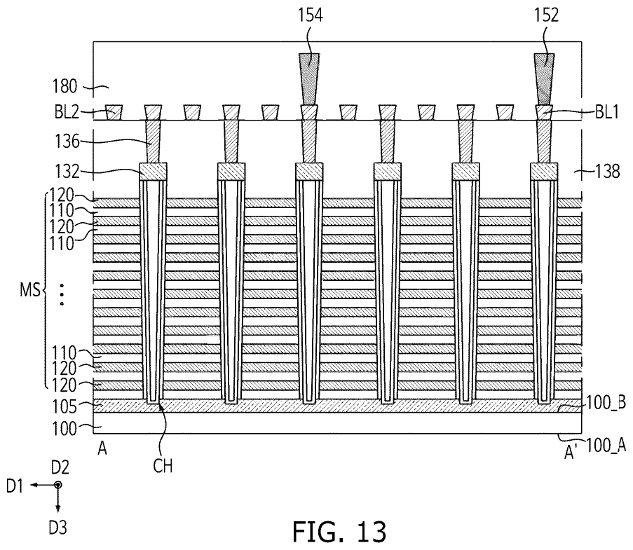

FIGS. 13 to 18 are diagrams showing intermediate stages, which are provided to explain a method of manufacturing a semiconductor memory device according to some example embodiments. For reference, FIGS. 13, 15, and 17 may correspond to cross-sectional views taken along line A-A′ of FIGS. 1 and 2, and FIGS. 14, 16, and 18 may correspond to cross-sectional views taken along line B-B′ of FIGS. 1 and 2. For convenience of description, the same configuration as the configurations described in FIGS. 1 to 12 will be omitted or briefly described.

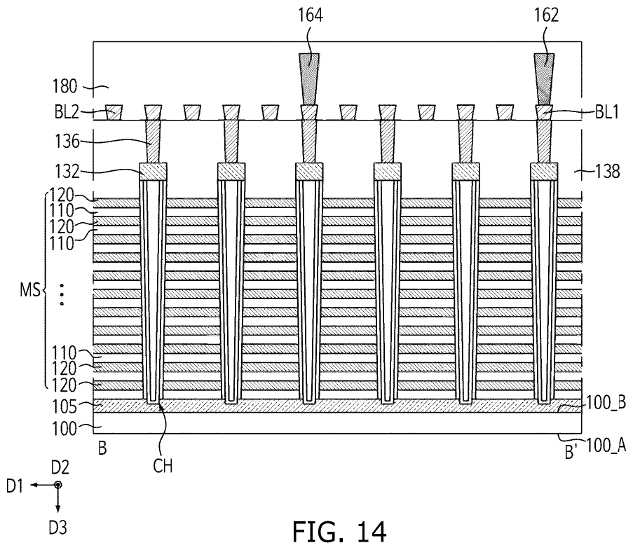

Referring to FIGS. 13 and 14, the common source plate 105, the mold structure MS, the channel structure CH, the channel pad 132, the bit line contact 136, and the cell interlayer insulating film 138 may be formed on the substrate 100. The plurality of first bit lines BL1 and the plurality of second bit lines BL2 may be formed on the cell interlayer insulating film 138. Each of the first bit line BL1 and the second bit line BL2 may extend in the second direction D2.

The first cell via 152 and the first dummy via 162 may be formed on the first bit line BL1, and the second cell via 154 and the second dummy via 164 may be formed on the second bit line BL2. The first cell via 152 and the second cell via 154 may be disposed in the upper interlayer insulating film 180. In some example embodiments, the first cell via 152 and the first dummy via 162 may be formed at the same time, and the second cell via 154 and the second dummy via 164 may be formed at the same time. In this case, the vias formed at the same time may mean that they are formed through the same process.

The upper interlayer insulating film 180 may surround the first cell via 152, the second cell via 154, the first dummy via 162, and the second dummy via 164. The upper interlayer insulating film 180 may cover the first cell via 152, the second cell via 154, the first dummy via 162, and the second dummy via 164.

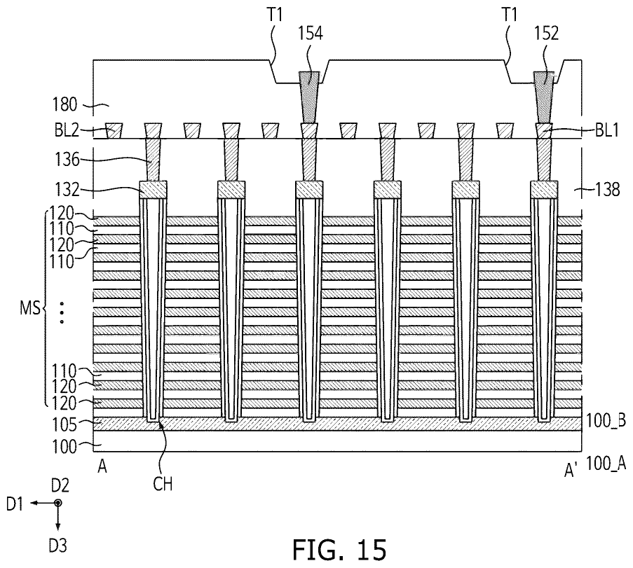

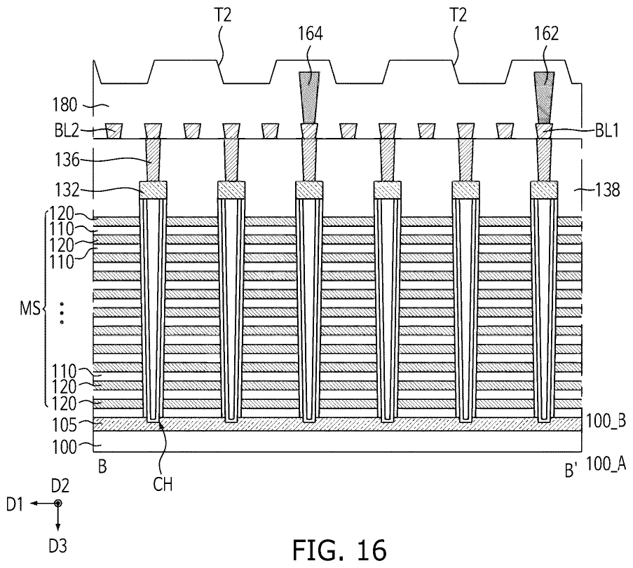

Referring to FIGS. 15 and 16, first trenches T1 and second trenches T2 may be formed on the upper interlayer insulating film 180. The first trenches T1 may expose portions of the first and second cell vias 152 and 154. One end of the first cell via 152 and one end of the second cell via 154 may protrude from bottom surfaces of the first trenches T1. The second trenches T2 may be disposed to be spaced apart from each of the first dummy via 162 and the second dummy via 164. The second trench T2 may not overlap with any of the first dummy via 162 and the second dummy via 164 in the third direction D3. Even if the second trench T2 is formed, the upper interlayer insulating film 180 may cover the first dummy via 162 and the second dummy via 164.

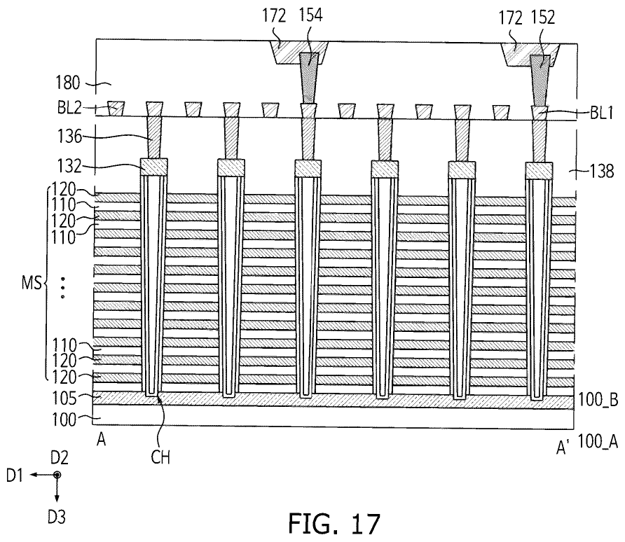

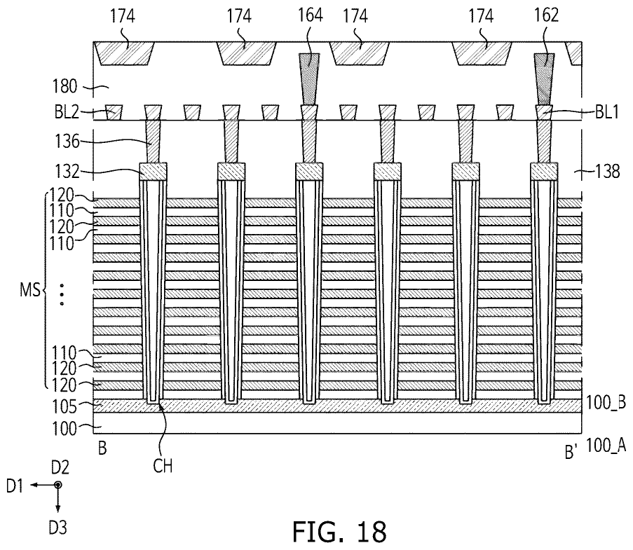

Referring to FIGS. 17 and 18, the first upper bonding pads 172 and the second upper bonding pads 174 may be formed on the upper interlayer insulating film 180. The first upper bonding pads 172 may fill the first trenches T1 (see FIG. 15). The first upper bonding pads 172 may be connected to corresponding ones of the first cell via 152 and the second cell via 154, respectively. The second upper bonding pads 174 may fill the second trenches T2 (see FIG. 16). The second upper bonding pads 174 may be disposed to be spaced apart from the first dummy via 162 and the second dummy via 164. The second upper bonding pads 174 may not be connected to the first dummy via 162 and the second dummy via 164.

Although it is illustrated that one end of the first cell via 152 and one end of the second cell via 154 are disposed in the first upper bonding pad 172, example embodiments are not limited thereto. For example, a depth of the first trench (T1 in FIG. 15) may be adjusted such that the upper surface of the first upper bonding pad 172 and the lower surface of the first cell via 152 may be in contact with each other as illustrated in FIG. 3. In addition, a depth of the second trench (T2 of FIG. 16) may be adjusted such that the second upper bonding pad 174 and the first dummy via 162 and the second dummy via 164 may not overlap in the first direction D1 as illustrated in FIG. 4.

Referring to FIGS. 6 and 7, the cell structure CELL and the peripheral circuit structure PERI may be bonded to each other to form the semiconductor memory device. For example, the first upper bonding pad 172 and the first lower bonding pad 272 may be bonded to each other, and the second upper bonding pad 174 and the second lower bonding pad 274 may be bonded to each other. The peripheral circuit structure PERI may be formed and provided on a wafer different from a wafer on which the cell structure CELL is formed.

FIG. 19 is an example block diagram provided to explain an electronic system according to some example embodiments.

Referring to FIG. 19, an electronic system 1000 may include a semiconductor memory device 1100 described with reference to FIGS. 1 to 18, and a controller 1200 electrically connected to the semiconductor memory device 1100. The electronic system 1000 may be a storage device including one or a plurality of semiconductor memory devices 1100 or an electronic device including the storage device. For example, the electronic system 1000 may be a solid-state drive device (SSD), a universal serial bus (USB), a computing system, a medical device, or a communication device, which may include one or the plurality of semiconductor memory devices 1100.

For example, the semiconductor memory device 1100 may be the NAND flash memory device described above with reference to FIGS. 1 to 18. The semiconductor memory device 1100 may include a first structure 1100F and a second structure 1100S on the first structure 1100F. The first structure 1100F may be a peripheral circuit structure including a decoder circuit 1110, the page buffer 1120, and the logic circuit 1130. The second structure 1100S may be a memory cell structure including the bit line BL, a common source line CSL, word lines WL, first and second gate upper lines UL1 and UL2, first and second gate lower lines LL1 and LL2, and memory cell strings CSTR between the bit line BL and the common source line CSL.

In the second structure 1100S, each of the memory cell strings CSTR may include lower transistors LT1 and LT2 adjacent to the common source line CSL, upper transistors UT1 and UT2 adjacent to the bit line BL, and a plurality of memory cell transistors MCT disposed between the lower transistors LT1 and LT2 and the upper transistors UT1 and UT2. The number of the lower transistors LT1 and LT2 and the number of the upper transistors UT1 and UT2 may vary according to various example embodiments.

In some example embodiments, the upper transistors UT1 and UT2 may include a string select transistor, and the lower transistors LT1 and LT2 may include a ground select transistor. The gate lower lines LL1 and LL2 each may be gate electrodes of the lower transistors LT1 and LT2. The word lines WL may be gate electrodes of the memory cell transistors MCT, and the gate upper lines UL1 and UL2 may be gate electrodes of the upper transistors UT1 and UT2, respectively.

The common source line CSL, the first and second gate lower lines LL1 and LL2, the word lines WL, and the first and second gate upper lines UL1 and UL2 may be electrically connected to the decoder circuit 1110 through first connection lines 1115 extending from within the first structure 1100F to the second structure 1100S. The bit lines BL may be electrically connected to the page buffer 1120 through second connection wires 1125 extending from within the first structure 1100F to the second structure 1100S.

In the first structure 1100F, the decoder circuit 1110 and the page buffer 1120 may perform a control operation on at least one select memory cell transistor among the plurality of memory cell transistors MCT. The decoder circuit 1110 and the page buffer 1120 may be controlled by the logic circuit 1130. The semiconductor memory device 1100 may communicate with the controller 1200 through an input/output pad 1101 electrically connected to the logic circuit 1130. The input and output pad 1101 may be electrically connected to the logic circuit 1130 through an input and output connection wiring 1135 extending from within the first structure 1100F and to the second structure 1100S.

The controller 1200 may include a processor 1210, a NAND controller 1220, and a host interface 1230. According to some example embodiments, the electronic system 1000 may include the plurality of semiconductor memory devices 1100, and in this case, the controller 1200 may control the plurality of semiconductor memory devices 1100.

The processor 1210 may control the overall operation of the electronic system 1000 including the controller 1200. The processor 1210 may operate according to desired (or alternatively, predetermined) firmware and may control the NAND controller 1220 to access the semiconductor memory device 1100. The NAND controller 1220 may include a NAND interface (or controller interface) 1221 that processes communication with the semiconductor memory device 1100. A control command for controlling the semiconductor memory device 1100, data to be written in the memory cell transistors MCT of the semiconductor memory device 1100, data to be read from the memory cell transistors MCT of the semiconductor memory device 1100, etc. may be transmitted through the NAND interface 1221. The host interface 1230 may provide a communication function between the electronic system 1000 and an external host. Upon receiving a control command from the external host through the host interface 1230, the processor 1210 may control the semiconductor memory device 1100 in response to the control command.

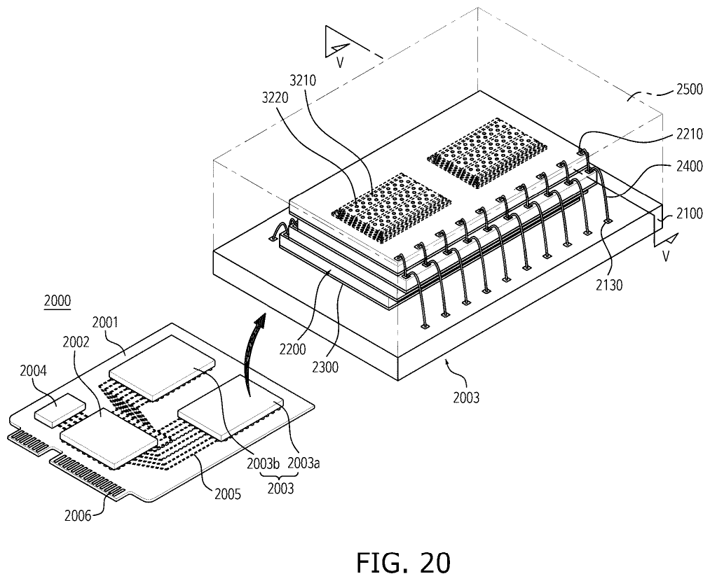

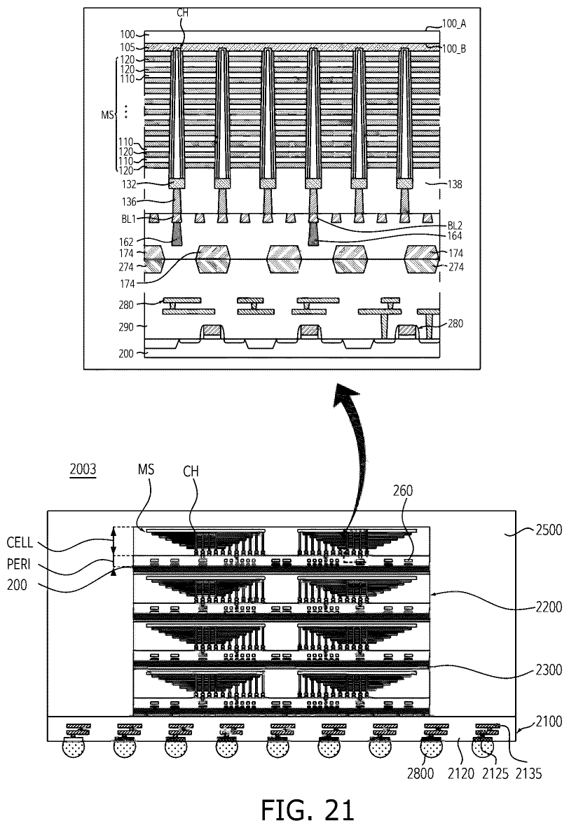

FIG. 20 is a perspective view provided as an example to explain an electronic system according to some example embodiments. FIG. 21 is a schematic cross-sectional view taken along line V-V′ of FIG. 20.

Referring to FIGS. 20 and 21, an electronic system 2000 may include a main substrate 2001, a controller 2002 mounted on the main substrate 2001, one or more semiconductor packages 2003, and a DRAM 2004. The semiconductor package 2003 and the DRAM 2004 may be connected to the controller 2002 by wiring patterns 2005 formed on the main substrate 2001.

The main substrate 2001 may include a connector 2006 including a plurality of pins coupled to the external host. The number and arrangement of the plurality of pins in the connector 2006 may vary depending on a communication interface between the electronic system 2000 and the external host. In some example embodiments, the electronic system 2000 may communicate with the external host according to any one of interfaces such as Universal Serial Bus (USB), Peripheral Component Interconnect Express (PCI-Express), Serial Advanced Technology Attachment (SATA), and M-Phy for Universal Flash Storage (UFS). In some example embodiments, the electronic system 2000 may be operated by the power supplied from the external host through the connector 2006. The electronic system 2000 may further include a Power Management Integrated Circuit (PMIC) that distributes the power supplied from the external host to the controller 2002 and the semiconductor package 2003.

The main controller 2002 may record data in the semiconductor package 2003 or read data from the semiconductor package 2003 and may improve the operation speed of the electronic system 2000.

The DRAM 2004 may be a buffer memory to alleviate the speed difference between the external host and the semiconductor package 2003 that is a data storage space. The DRAM 2004 included in the electronic system 2000 may also operate as a kind of cache memory and may also provide a space for temporarily storing data in a control operation for the semiconductor package 2003. If the electronic system 2000 includes the DRAM 2004, in addition to the NAND controller for controlling the semiconductor package 2003, the main controller 2002 may further include a DRAM controller for controlling the DRAM 2004.

The semiconductor package 2003 may include first and second semiconductor packages 2003a and 2003b spaced apart from each other. Each of the first and second semiconductor packages 2003a and 2003b may be a semiconductor package including a plurality of semiconductor chips 2200. Each of the first and second semiconductor packages 2003a and 2003b may include a package substrate 2100, the semiconductor chips 2200 on the package substrate 2100, adhesive layers 2300 disposed on a lower surface of each of the semiconductor chips 2200, a connection structure 2400 electrically connecting the semiconductor chips 2200 and the package substrate 2100, and a molding layer 2500 covering the semiconductor chips 2200 and the connection structure 2400 on the package substrate 2100.

The package substrate 2100 may be a printed circuit board including package upper pads 2130. Each of the semiconductor chips 2200 may include an input/output pad 2210. The input/output pad 2210 may correspond to the input/output pad 1101 of FIG. 19. Each of the semiconductor chips 2200 may include metal lines 3210 and channel structures 3220. Each of the semiconductor chips 2200 may include the semiconductor memory device described above with reference to FIGS. 1 to 18.

In some example embodiments, the connection structure 2400 may be a bonding wire electrically connecting the input and output pad 2210 to the package upper pads 2130. Therefore, in each of the first and second semiconductor packages 2003a and 2003b, the semiconductor chips 2200 may be electrically connected to each other with the bonding wire method and may be electrically connected to the package upper pads 2130 of the package substrate 2100. In some example embodiments, in each of the first and second semiconductor packages 2003a and 2003b, the semiconductor chips 2200 may be electrically connected to each other through a connection structure including Through Silicon Via (TSV) instead of a bonding wire type connection structure 2400.

In some example embodiments, the main controller 2002 and the semiconductor chips 2200 may be included in one package. In some example embodiments, the main controller 2002 and the semiconductor chips 2200 may be mounted on a separate interposer substrate different from the main substrate 2001, and the main controller 2002 and the semiconductor chips 2200 may be connected to each other through wiring formed on the interposer substrate.

In some example embodiments, the package substrate 2100 may be a printed circuit board. The package substrate 2100 may include a package substrate body portion 2120, the package upper pads 2130 disposed on an upper surface of the package substrate body portion 2120, lower pads 2125 disposed on a lower surface of the package substrate body portion 2120 or exposed through the lower surface, and internal wires 2135 electrically connecting the upper pads 2130 and the lower pads 2125 inside the package substrate body portion 2120. The upper pads 2130 may be electrically connected to the connection structures 2400. The lower pads 2125 may be connected to the wiring patterns 2005 of the main substrate 2001 of the electronic system 2000 through conductive connections 2800, as illustrated in FIG. 20.

In an electronic system according to some example embodiments, each of the semiconductor chips 2200 may include the semiconductor memory device described above with reference to FIGS. 1 to 18. For example, each of the semiconductor chips 2200 may include the cell structure CELL and the peripheral circuit structure PERI stacked on the cell structure CELL. For example, the cell structure CELL may include the first bit line BL1, the second bit line BL2, the first cell via 152, the second cell via 154, the first dummy via 162, the second dummy via 164, the upper bonding pads 172 and 174, etc. described above with reference to FIGS. 1 to 18. In addition, for example, the peripheral circuit structure PERI may include the peripheral circuit substrate 200, the peripheral circuit element 260, and the lower bonding pads 272 and 274 described above using FIGS. 1 to 18.

Any functional blocks shown in the figures and described above may be implemented in processing circuitry such as hardware including logic circuits, a hardware/software combination such as a processor executing software, or a combination thereof. For example, the processing circuitry more specifically may include, but is not limited to, a central processing unit (CPU), an arithmetic logic unit (ALU), a digital signal processor, a microcomputer, a field programmable gate array (FPGA), a System-on-Chip (SoC), a programmable logic unit, a microprocessor, application-specific integrated circuit (ASIC), etc.

Although certain example embodiments of the present disclosure have been described with reference to the accompanying drawings, those of ordinary skill in the art to which the present disclosure pertains will understand that the present disclosure may be implemented in other specific forms without changing its technical idea or essential features. Therefore, it should be understood that the example embodiments described above are illustrative and non-limiting in all respects.

What is claimed is:

1. A semiconductor memory device, comprising:
a mold structure on a substrate and including a plurality of gate electrodes stacked and spaced apart from each other in a first direction;
a channel structure penetrating through the mold structure;
a bit line connected to the channel structure and extending in a second direction intersecting with the first direction;
a cell via on the bit line;
a dummy via on the bit line and spaced apart from the cell via in the second direction;
an upper interlayer insulating film surrounding the cell via and the dummy via;
a first upper bonding pad on the cell via; and
a second upper bonding pad spaced apart from the first upper bonding pad in the second direction, wherein
the upper interlayer insulating film covers a lower surface of the dummy via.

2. The semiconductor memory device according to claim 1, wherein
the second upper bonding pad is adjacent to the dummy via, and
the dummy via is spaced apart from the second upper bonding pad.

3. The semiconductor memory device according to claim 1, wherein a lower surface of the cell via and the lower surface of the dummy via are at a same vertical level.

4. The semiconductor memory device according to claim 1, wherein the second upper bonding pad does not overlap the bit line in the first direction.

5. The semiconductor memory device according to claim 1, wherein a width of the cell via in the second direction is same as a width of the dummy via in the second direction.

6. The semiconductor memory device according to claim 1, wherein a width of the cell via in the second direction is less than a width of the dummy via in the second direction.

7. The semiconductor memory device according to claim 1, further comprising:
a third upper bonding pad spaced apart from the second upper bonding pad in a third direction intersecting with each of the first direction and the second direction, wherein
the dummy via is between the second upper bonding pad and the third upper bonding pad.

8. The semiconductor memory device according to claim 1, wherein one end of the cell via penetrates through an upper surface of the first upper bonding pad.

9. The semiconductor memory device according to claim 1, wherein one end of the dummy via overlaps the second upper bonding pad in a third direction intersecting with each of the first direction and the second direction.

10. The semiconductor memory device according to claim 1, wherein the dummy via is not connected to the second upper bonding pad.

11. A semiconductor memory device, comprising:
a mold structure on a substrate;
a channel structure penetrating through the mold structure and extending in a first direction;
a first bit line connected to the channel structure and extending in a second direction intersecting with the first direction;
a first cell via on the first bit line;
a first dummy via on the first bit line and spaced apart from the first cell via in the second direction;
an upper interlayer insulating film surrounding the first cell via and the first dummy via;
a first upper bonding pad on the upper interlayer insulating film and connected to the first cell via; and
a second upper bonding pad on the upper interlayer insulating film and not overlapping the first dummy via in the first direction.

12. The semiconductor memory device according to claim 11, further comprising:
a second bit line spaced apart from the first bit line in a third direction intersecting with each of the first direction and the second direction, the second bit line extending in the second direction;
a second cell via on the second bit line; and
a second dummy via on the second bit line and spaced apart from the second cell via in the second direction.

13. The semiconductor memory device according to claim 12, wherein
the first cell via and the second cell via overlap each other in the third direction, and
the first dummy via and the second dummy via overlap each other in the third direction.

14. The semiconductor memory device according to claim 12, further comprising:
a third bit line between the first bit line and the second bit line.

15. The semiconductor memory device according to claim 11, wherein a width of the first cell via in a third direction intersecting with each of the first direction and the second direction is greater than a width of the first bit line in the third direction.

16. The semiconductor memory device according to claim 11, wherein a width of the first cell via in a third direction intersecting with each of the first direction and the second direction is same as a width of the first dummy via in the third direction.

17. The semiconductor memory device according to claim 11, wherein a lower surface of the first cell via and a lower surface of the first dummy via are on a same plane.

18. The semiconductor memory device according to claim 11, further comprising:
a channel pad on the channel structure; and
a bit line contact between the channel pad and the first bit line.

19. The semiconductor memory device according to claim 11, further comprising:
a first lower bonding pad on the first upper bonding pad; and
a second lower bonding pad on the second upper bonding pad, wherein
an upper surface of the first lower bonding pad and an upper surface of the second lower bonding pad are on a same plane.

20. An electronic system, comprising:
a main substrate;
a semiconductor memory device comprising a cell structure on the main substrate and a peripheral circuit structure on the cell structure; and
a controller on the main substrate and electrically connected to the semiconductor memory device, wherein
the cell structure comprises
a mold structure on a substrate and comprising a plurality of gate electrodes stacked and spaced apart from each other in a first direction,
a channel structure penetrating through the mold structure and extending in the first direction,
a bit line connected to the channel structure and extending in a second direction intersecting with the first direction,
a cell via on the bit line,
a dummy via on the bit line and spaced apart from the cell via in the second direction,
an upper interlayer insulating film surrounding the cell via and the dummy via,
a first upper bonding pad on the upper interlayer insulating film and connected to the cell via, and
a second upper bonding pad on the upper interlayer insulating film and not overlapping the dummy via in the first direction, and
the upper interlayer insulating film covers a lower surface of the dummy via.
